(19) United States
(12) Patent Application Publication
(10) Pub. No.: US 2025/0255055 A1
(43) Pub. Date: Aug. 7, 2025

(54) ASYMMETRIC MONOLITHIC RED-GREEN-BLUE (RGB) MICROSCOPIC LIGHT-EMITTING DIODE (MICROLED) PANEL

(71) Applicant: GOOGLE LLC, Mountain View, CA (US)

(72) Inventors: Jun Yang, Mountain View, CA (US); Joseph Daniel Lowney, Tucson, AZ (US); Thomas Hoekman, Redwood City, CA (US)

(21) Appl. No.: 18/434,350

(22) Filed: Feb. 6, 2024

(51) Int. Cl. H01L 33/58; G06F 3/01; G06T 19/00; H01L 25/075; H01L 33/46

(52) U.S. Cl. CPC H10H 20/855; G06F 3/011; G06T 19/006; H01L 25/0753; H10H 20/841; H10H 20/034; H10H 20/0363

(57) ABSTRACT

An augmented reality (AR) display includes a light engine having a three-color microscopic light-emitting diode (microLED) panel and an array of microlenses disposed at the three-color microLED panel and configured to redirect collimated projected light from the three-color microLED panel to an exit pupil of the light engine. A microlens of the array of the microlenses partially covers a pixel of the three-color microLED panel so that a red pixel of the three-color microLED panel is substantially aligned with an optical axis of each microlens and a blue pixel and a green pixel are substantially offset from the microlens. A waveguide of the AR display includes an input coupler (IC) with an entrance pupil that is substantially coplanar with the light engine.

### BACKGROUND

A red-green-blue (RGB) microscopic light-emitting diode (microLED) panel can be used to create images on diffractive waveguide-based augmented reality (AR)-based near eye displays. Unlike traditional LED displays or organic LED (OLED) displays, microLED uses an array of relatively small LEDs, each capable of separately emitting light, which allows for more control over individual pixels. This results in enhanced contrast, improved black levels, and enhanced overall picture quality, while allowing for higher pixel densities, enabling sharper images and potentially thinner displays.

Monolithic color microLED technology has potential as a display solution for AR applications. The energy usage correlates with the number of active pixels, making it efficient when rendering less dense content. Furthermore, the monolithic design simplifies the light engine system, potentially reducing integration costs. The active segment of a microLED emits light in a Lambertian pattern. To gather, collimate, and direct this light toward a waveguide-based optical combiner (“waveguide combiner”) for providing a view of the real world overlayed with static imagery or video (recorded or rendered), a lens with a relatively large numerical aperture may be used, however, constraints on display size, weight, and cost often make it unfeasible. Consequently, many light engine designs exhibit notably low optical efficiency.

Panel ghost artifacts are visual irregularities that arise when light, initially reflected from the input coupler (IC) within the waveguide, re-enters the light engine. Subsequently, this light is reflected by the display panel and manages to return to the IC, ultimately coupling back into the waveguide. The strength and visibility of these ghost artifacts are significantly influenced by the reflective properties inherent to the display panel. The term ‘ghost panel artifacts’ refers to undesired visual anomalies that occur within display systems, particularly in technologies like augmented reality (AR) or head-up displays (HUDs). These artifacts arise due to the internal reflections and interactions of light among different components within the display setup. These visual disturbances are a result of light bouncing or reflecting between various elements of the display, such as the waveguide, display panel, and IC. Light emitted from one component may unintentionally reflect off another, leading to unintended images or distortions visible to the viewer. Several factors contribute to the creation of these ghost panel artifacts.

One factor is the reflection of light within the display system, causing multiple reflections that interfere with the intended image or information being displayed. The reflective properties of the materials used in the display panel or waveguide significantly influence the occurrence and severity of these artifacts. Materials with high reflectivity are more likely to cause unintended reflections and ghosting. The design and optics of the display system play a crucial role. Proper placement of components and the use of materials with optimal optical properties help manage light effectively and reduce unwanted reflections. Additionally, external factors such as ambient lighting conditions can also contribute to ghosting, as reflections from the surroundings interfere with the display. To mitigate ghost panel artifacts, display designers employ various techniques. These may include applying anti-reflective coatings to surfaces, optimizing the optical design to minimize internal reflections, using materials with lower reflective indices, and employing improved light management strategies. By addressing these factors, display systems can minimize unintended reflections, ensuring that the displayed content remains clear and free from ghosting or other visual distortions, thereby enhancing the overall user experience in AR, HUDs, and similar display technologies.

Current methods for reducing ghost panel artifacts involve employing several strategies within display system design and implementation. One approach is to utilize anti-reflective coatings on various components, such as the display panel and waveguide surfaces, to minimize internal reflections and scatterings of light. Optimizing the optical design and placement of components is crucial to manage light paths and minimize unintended reflections. This includes selecting materials with lower reflective indices and designing the system to control the direction and propagation of light to prevent reflections that could lead to ghosting. Improving the quality of the components used in the display system also plays a significant role in mitigating ghosting. Higher-quality materials and manufacturing processes may reduce reflective surfaces and enhance the overall optical performance of the system. Implementing light management techniques, such as employing diffusers or optical coatings, may help control the distribution of light and reduce the likelihood of reflections within the display system. As a result of combining these approaches, ghosting may be minimized and the visual clarity and quality of the displayed content in AR may be improved.

Further approaches to diminish “panel ghost” artifacts include tilting the waveguide to redirect reflected light towards an optical stop, diminishing the exit pupil size by incorporating an aperture or redesigning the projector, or reducing the size of the IC in the incoupling direction to align with the waveguide thickness. However, each of these solutions presents specific challenges. In an example, tilting the waveguide may encounter limitations within the product design, as accommodating a relatively large angle for the waveguide element might be impractical. Moreover, it could potentially increase the overall product volume, and for a significant field of view (FOV), the required tilt angle might become unmanageable, necessitating a tilt close to half the FOV to diminish ghost artifacts.

Reducing the exit pupil size, based on the conservation of etendue, necessitates a decrease in the total optical power transferred by the system. Notably, different colors have distinct optimal exit pupil sizes. Therefore, if a ghost contrast specification is standardized across all colors (which might be logical for a photopic specification), the exit pupil size is dictated by the poorest color channel. In diffractive waveguide designs, blue tends to be the limiting channel. However, from a system-level perspective, red efficiency often poses the most significant challenge. Red waveguide efficiencies tend to be lower, and in the case of microLED panels, red is inherently inefficient. As blue is spectrally farthest from red, reducing the exit pupil size presents a tradeoff between red efficiency and RGB ghost contrast. Whether achieved by absorption with a mask or by diminishing the IC size, this design challenge persists.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a diagram of the IC coupling efficiency for a RGB pixel array in the IC region of a waveguide configured to be paired with a light engine to form a display system in accordance with some embodiments.

FIG. 2 is a diagram of a waveguide having an IC aligned with an optional exit pupil expander (EPE) with an IC direction shown as the IC k-vector that may be implemented with a RGB microlens array on a microLED panel in accordance with some embodiments.

FIG. 3 is a diagram illustrating spatial variation of rebounce and efficiency in the IC of a waveguide in accordance with some embodiments.

FIG. 4 is a diagram illustrating a display system of a light engine and waveguide with a monochrome green display having a microLED panel with a pixel array with a projection lens and without a microlens in accordance with some embodiments.

FIG. 5 is a diagram illustrating the display system with a light engine and waveguide with monochrome green display having a microLED panel with a pixel array of FIG. 4 with a projection lens and a microlens in accordance with some embodiments.

FIG. 6 is a diagram illustrating the display system of a light engine and waveguide with a monolithic multi-color display having a microLED panel with a pixel array with a projection lens and a microlens in accordance with some embodiments.

FIG. 7 is a diagram illustrating the display system of a light engine and waveguide with a monolithic multi-color display having a microLED panel with a pixel array with a projection lens of FIG. 6 with the microlens array offset so that the optical axis is aligned with the red pixel in accordance with some embodiments.

FIG. 8 is a diagram illustrating a rear perspective view of a set of AR glasses with at least one lens employing a waveguide of FIG. 7 with a monolithic multi-color display having a microLED panel with a pixel array, a projection lens, and a microlens array offset and/or asymmetrical so that the optical axis is aligned with the red pixel in accordance with some embodiments.

### DETAILED DESCRIPTION

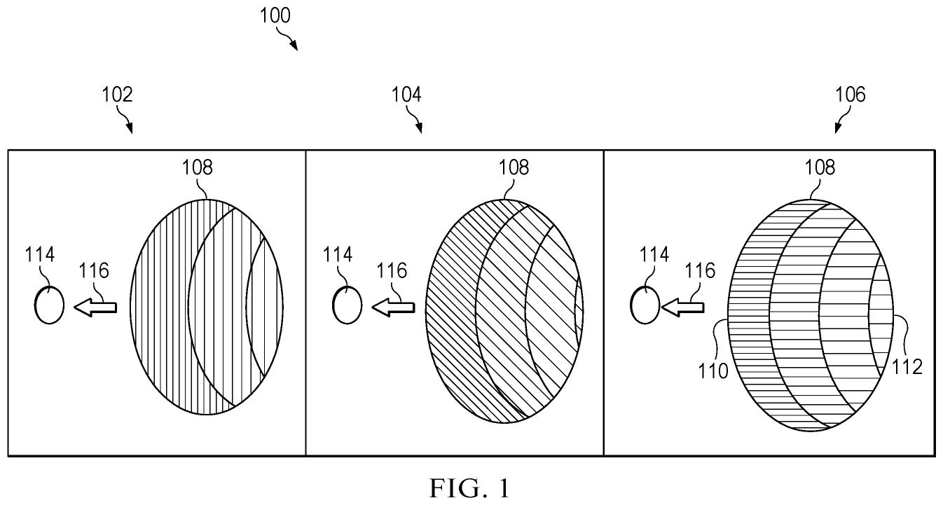

FIGS. 1-8 illustrate example systems and methods for utilizing light emitted from RGB subpixels within a microLED panel that may be optimized differentially. Within a diffractive waveguide system, the efficiency of coupling red, green, and blue light varies, which may be exploited through configuration of a microlens array and an input coupler. As a result, it becomes practical to curtail losses associated with specific colors, consequently elevating the overall efficiency of the system. For the development of a comprehensive display system, use of a light engine often results in corresponding use of a waveguide. In an effort to enhance light collection efficiency, a microscopic lens (microlens) array positioned directly above the pixels may prove to be effective. This array alters the panel's Lambertian emission pattern into a more directional profile, allowing for more efficient coupling by the projector. However, for an RGB three-color microLED panel, the effectiveness of a microlens array is limited due to the increased active area within each pixel in a monolithic multi-color microLED panel. Consequently, the microlens encounters difficulties in collecting light from a larger area, leading to challenges in effectively collimating light without significant losses due to the etendue limit. In the context of a diffractive waveguide, the uniformity of coupling efficiency for RGB light within the input coupler region is disrupted by what is termed as “rebounce” loss (refer to FIG. 1).

FIG. 1 illustrates a coupling efficiency for light of a RGB pixel array of a first pixel 102, a second pixel 104, and a third pixel 106 in a waveguide IC region 100 of a diffractive waveguide (not shown in FIG. 1) configured to be paired with a light engine (not shown) to form a display system. The coupling efficiency where the region is closest to the EPE of the waveguide is in the IC coupling direction 116 and has lower rebound loss and thus higher efficiency. The region of the IC of the waveguide closer to an EPE 114 exhibits heightened in-coupling efficiency. Furthermore, owing to the disparate propagation angles of red, green, and blue light within the waveguide, red incurs a smaller rebound loss in comparison to green, while blue experiences the most substantial rebound loss.

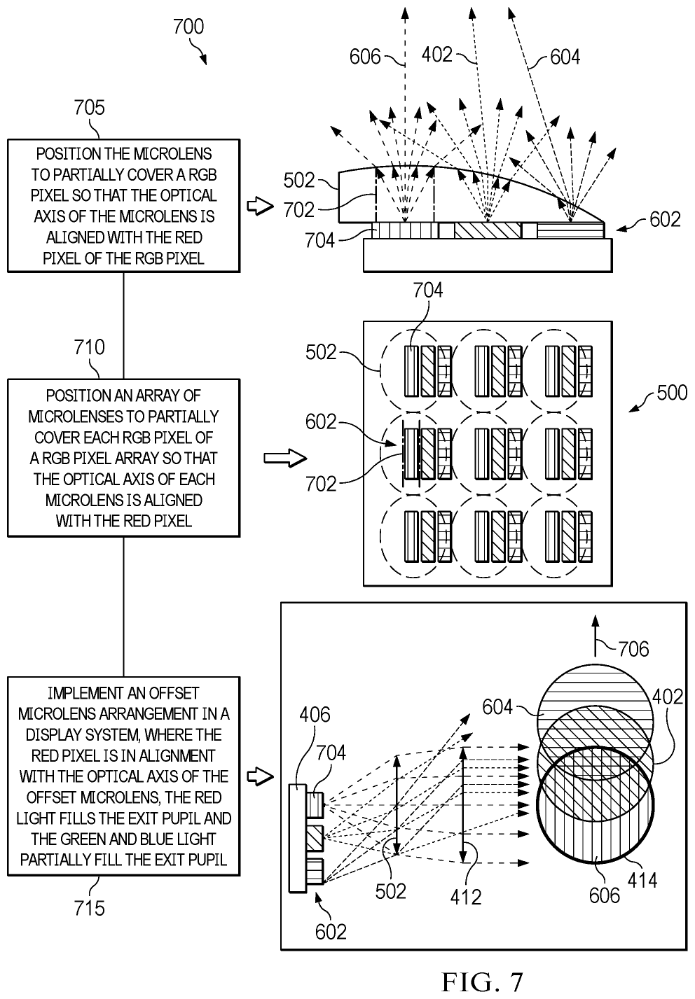

In an example for blue light, as it fills the entirety of an exit pupil 108 of the light engine, the IC region 100 does not couple light uniformly in terms of efficiency. If light is coupled closest to edge 110 of the exit pupil, the greatest amount of blue light is coupled into the waveguide. Light is lost or not coupled into the waveguide when blue light experiences rebounce from the waveguide closer to an edge 112 of an exit pupil 108. The efficiency drop is different for different colors. Red light has less of an efficiency drop than green light and blue light. Blue light enters a waveguide at a steeper angle and experiences an increase in rebounce, while red light travels through the waveguide at a more oblique angle and experiences a decrease in rebounce. Leveraging this asymmetry in the efficiency of the waveguide IC region 100 among red light, green light, and blue light, a method and structure for incoupling RGB light as described herein involves configuring a microlens array to be offset and/or asymmetric so that the optical axis is aligned with a red pixel on the microLED panel to minimize additional loss (as described in more detail in FIG. 7).

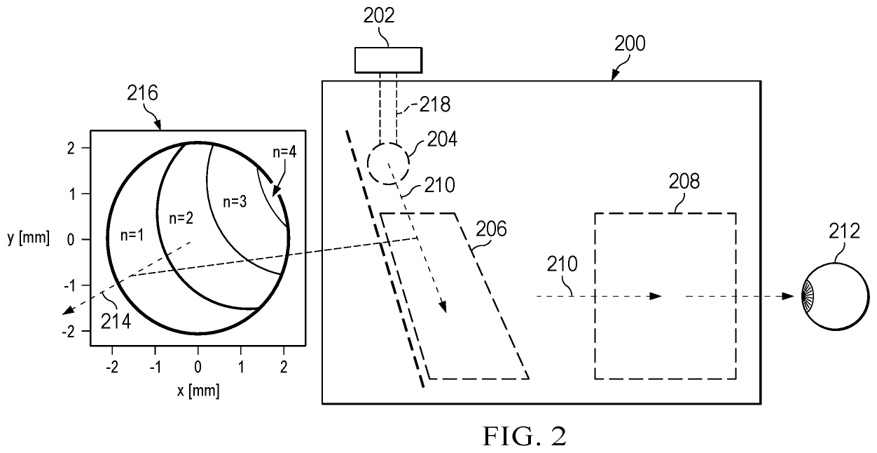

Turning now to FIG. 2, an example waveguide 200 that has an IC k-vector with a coupling efficiency relationship between each color channel and EPE diameter. The illustrated waveguide 200 is suitable for pairing with a light engine 202 to form a display system for improved coupling efficiency and/or other reasons in accordance with embodiments. The waveguide 200, in some implementations, includes an IC 204, an EPE 206, and an output coupler (OC) 208. An entrance pupil of the IC 204 is configured to receive display light 210 from the exit pupil of the light engine 202 and/or another light source. In implementations that include an EPE, the EPE 206 is configured to increase the size of the display exit pupil. The position of the IC 204 typically is tied to the position of the EPE 206; that is, the IC 204 is aligned with EPE 206. In other words, they are adjusted and aligned in a way that facilitates the smooth transition of light from one component to the other. The OC 208 is configured to direct the resulting display light 210 toward a user's eye 212. This combination of components operates together for the display light to reach the user's eye in the intended manner. For a given IC geometry and IC k-vector 214, the number of times the ray from display light 210 will interact with a diffraction grating of the waveguide is dependent on position. The closer the ray is to the edge of the IC (in the direction of in-coupling), the fewer bounces it will experience in the IC region. An example of this is shown in FIG. 2 for a circular IC geometry 216. The depicted n-number (e.g., n=1, n=2, etc.) represents the number of interactions with the diffraction grating, and the in-coupling direction is shown as the IC k-vector 214; thus, the IC k-vector 214 is the direction of the grating configured to direct display light 210 into the IC of the waveguide.

Areas of the IC 204 further from the incoupling edge have a lower coupling efficiency due to rebounce, and contribute proportionally more to ghost panel artifacts. For diffractive combiner designs that have an exit pupil diameter substantially larger than the waveguide thickness, it is typical for a relatively large region of the exit pupil to have high ghost panel artifact (regions where n>1). The size of these regions is wavelength dependent as the bounce spacing of light has a very strong effect on rebounce loss. The use of a microlens array on a microLED panel results in a translation offset between the exit pupil of each color channel, shifting the blue exit pupil along the IC k vector. This results in less blue light incident on regions n=3 and n=4 while having little effect on the blue flux incident on region n=1. Thus, the incoupling efficiency is only marginally affected, while blue light rebounce, and therefore blue light ghost intensity is reduced. The opposite effect is present for longer wavelengths, since the exit pupil is shifted in the opposite direction. However, since the size of the high efficiency n=1 region is larger for red light than for blue light, the drop in efficiency and/or increase in reflection for larger wavelengths is much less than the improvement seen in blue light.

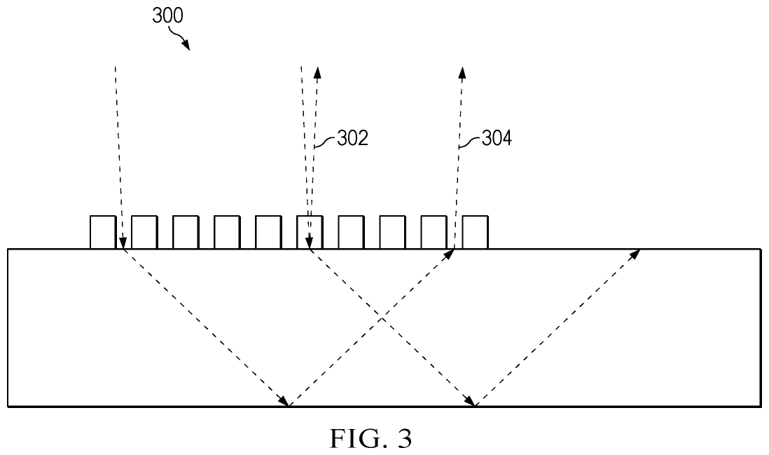

FIG. 3 illustrates this rebound effect within a waveguide 300 that has two main waveguide reflection ray paths through an IC, which contributes to panel ghost artifacts being direct reflections 302 and rebounce reflections 304. Direct reflections 302 are zero-eth order specular reflection from the input coupler. Rebounce reflections 304 are ray paths that undergo any non-zero diffraction event in the IC, where the sum of all diffraction event order is 0 (Σm=0). When optimizing the IC grating structure for efficiency, it is common to end up in a regime where rebounce paths dominate. This is because as incoupling diffraction efficiency is maximized, the direct reflections 302 is minimized, while the rebounce reflection 304 is maximized.

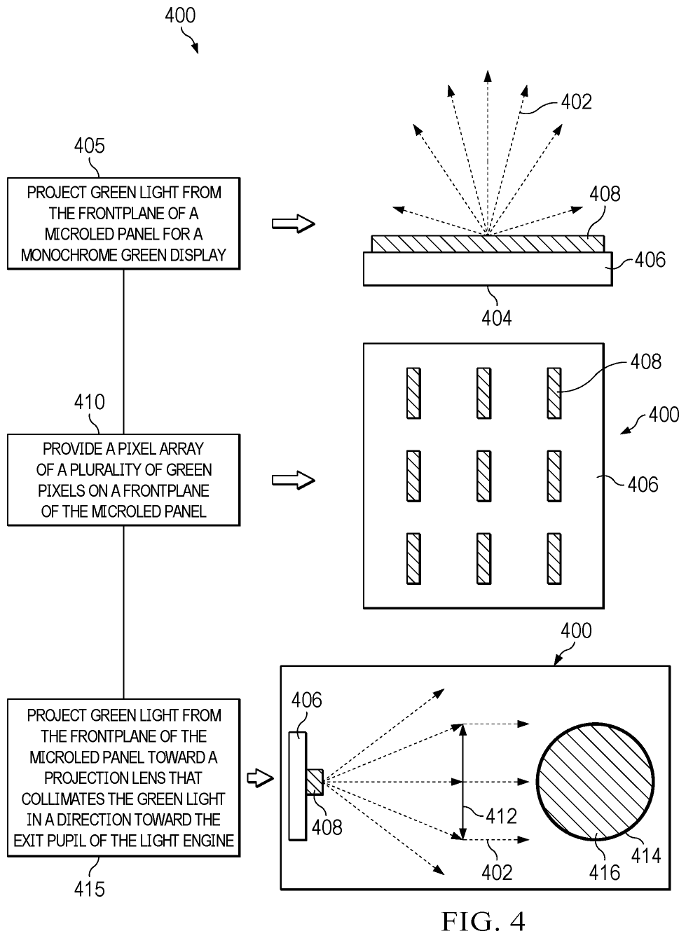

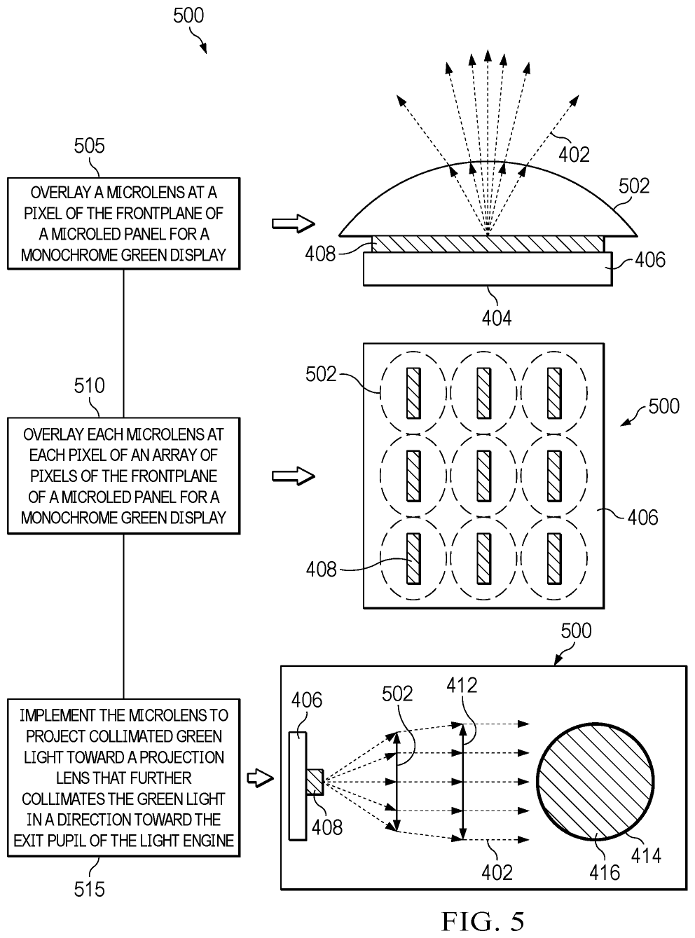

FIG. 4 illustrates a display system 400 of a light engine and a waveguide with a monochrome green display having a microLED panel with a pixel array with a projection lens and without a microlens, and a method of its operation. At block 405, green light 402 is projected from a frontplane 404 of a microLED panel 406 for a monochrome green display. Since there is no microlens present within display system 400, the light projection, at each pixel 408 gives a relatively larger angle range with less collimation. At block 410, a display system 400 is provided that has a microLED panel 406 with an array of pixels 408 configured to project green light from the frontplane 404 of the microLED panel 406. At block 415, an array of pixels 408 of microLED panel 406 projects green light 402. Projection lens 412 collimates the green light 402 from each pixel 408 together towards the exit pupil 414 of the light engine assembly and results as a disk of light 416 that is parallel with the entrance pupil of the IC of a waveguide. In an embodiment, the exit pupil 414 of the light engine is substantially coplanar 218 (FIG. 2) with an IC 204 of a waveguide 200 and wherein the collimated projected light is redirected to an entrance pupil (not shown) of the IC 204 of the waveguide 200. The projector's low collection efficiency results in low overall efficiency due to lost light and an addition of a microlens to the system, as shown in FIG. 5 will help to collimate more of the light to increase the projector efficiency and to produce a brighter exit pupil.

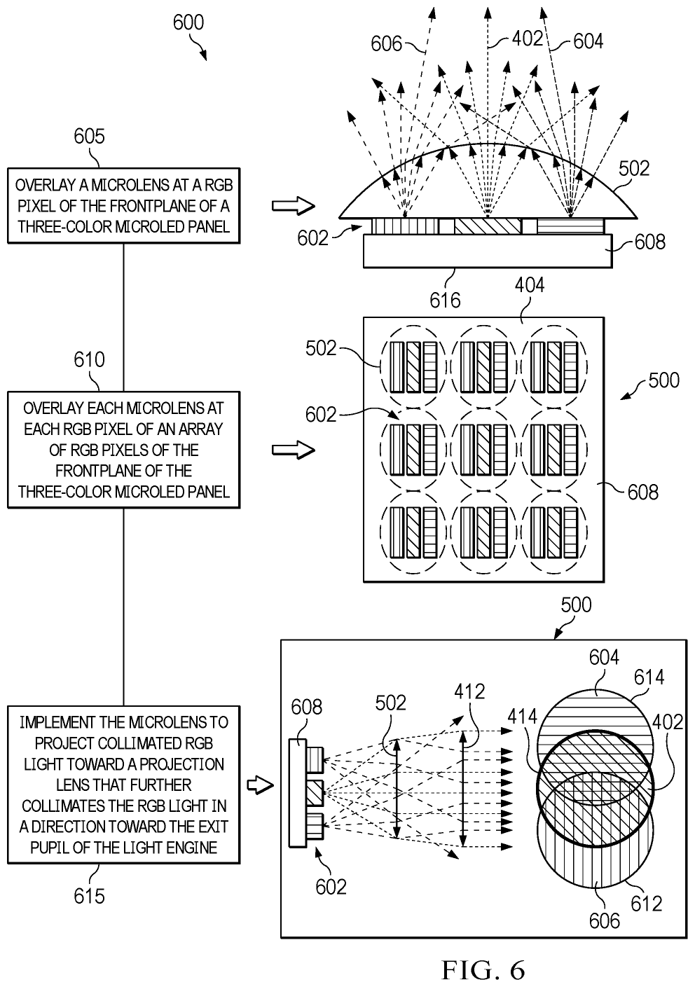

FIG. 5 illustrates a display system 500 having a light engine and waveguide with the monochrome green display having a microLED panel with a pixel array with a projection lens of FIG. 4, and a matching microlens array, as well as a method of its operation. At block 505, a microlens 502 is overlaid at a pixel 408 of the frontplane 404 of a microLED panel 406 of a display system 500. At block 510, each microlens 502 is overlaid at each pixel 408 of an array of pixels of the frontplane 404 of a microLED panel 406 of monochrome green display of a display system 500. At block 515, the microlens 502 is implemented to collimate the projected green light 402 toward a projection lens 412 that further collimates the green light 402 in a direction toward an exit pupil 414 of the light engine so as to reduce the angular spread of green light 402 from the microLED panel 406 for a monochrome green display by collimating the projected green light 402. As a result, projector efficiency is increased and a brighter disk of light 416 of exit pupil 414 is produced. The microlens 502 redirects light from the pixels 408 at a larger angle to a smaller angle to the projection lens 412. The projection lens further collimates the green light 402 at a higher intensity to the exit pupil 414. A problem occurs when the area of a pixel in a pixel array is large and the gap in between pixels is very small in the case of a multi-color microLED panel as shown in FIG. 6.

FIG. 6 illustrates a display system 600 having a monolithic three-color microLED panel 608 with an RGB pixel array rather than the monochrome green pixel array illustrated in FIG. 5, as well as a method of its operation. Display system 600 has a light engine and waveguide with a monolithic three-color microLED panel 608 with a RGB pixel array with a projection lens 412 and a matching microlens 502 array. At block 605, a microlens 502 is overlaid at the RGB pixel 602 of the frontplane 616 of the three-color microLED panel 608. The microlens 502 collimates the blue light 604, the green light 402, and the red light 606 of the RGB pixels 602. At block 610, each microlens 502 is overlaid at an array of RGB pixels of the frontplane 616 of the three-color microLED panel 608. In some embodiments, each microlens 502 covers each RGB pixel 602 within the array. The microlens 502 may be connected to the light engine or placed between the RGB pixels 602 and a waveguide with a gap. An optical coating, a buffer layer and/or an air gap may be located between the RGB pixels 602 and the microlens 502. At block 615, the microlens 502 is implemented to project the collimated RGB light toward the projection lens 412, which further collimates the RGB light in a direction toward the exit pupil 414 of the light engine so as to reduce the angular spread of projected green light 402, blue light 604, and red light 606 from the monolithic three-color microLED panel 608.

Typically, the microlens 502 does not collimate all colors of the RGB pixels 602 on the monolithic three-color microLED panel 608 in the same direction, resulting in an uneven exit pupil. The imaging circle 612 from the red pixels and the imaging circle 614 from the blue pixels are offset from the optical axis and are clipped by the projector's exit pupil 414, resulting in a loss of light. The blue light 604 will partially fill the exit pupil 414. The red light 606 will partially fill exit pupil 414. Since the green pixel is substantially centered in the central portion of the three-color microLED panel 608, the green light 402 will fill the exit pupil 414. This microlens 502 will project a different portion of the light emitted from the pixels and the projection lens 412 will shift the collimated light at a different position so that light will be lost. With the microlens 502 array, there is a trade-off between a light intensity at a peak intensity and occupying a smaller region. The RGB light partially fills the exit pupil 414 and efficiency typically is still lost. FIG. 7 shows the display system 500 of FIG. 6, except with a shifted microlens array oriented to substantially position the red pixel towards the central portion of the microlens compared to the green light and the blue light of the RGB pixels 602 so as to increase efficiency. As a net result in an augmented reality (AR) application, the waveguide experiences less rebounce when the red color is used because it has a lower efficiency drop than the green light and blue light nonuniformity in terms of IC efficiency. Thus, the ghost panel artifacts may be reduced.

FIG. 7 illustrates a display system 700 with an offset microlens array implemented in the display system 600 of FIG. 6, as well as a method of its operation. Display system 700 has a light engine and waveguide with a monolithic multi-color microLED panel with a RGB pixel 602 array with a projection lens 412 and an offset microlens array. At block 705, the microlens 502 is positioned to partially cover the RGB pixel so that the optical axis of the microlens 502 is aligned with the red pixel of the RGB pixel. The microlens 502 is offset and shifted so that its optical axis 702 is aligned with red pixel 704 of the RGB pixels 602. The red light 606 has the same coupling efficiency as the green light 402 in FIG. 4, however the blue light 604 and the green light 402 have asymmetric coupling efficiency. If the RGB pixels 602 of the display panel are designed such that the blue pixel relative to the red pixel is spatially placed along the direction of the input coupler, then the blue pixel will have a profile offset to the input coupler direction, which is also where the waveguide coupling efficiency for blue light is highest. In this case, there is much lower loss for green and blue, and overall higher total efficiency for all three colors. At block 710, an array of microlenses is positioned to partially cover each RGB pixel of the RGB pixel array so that the optical axis of each microlens is aligned with the red pixel. At block 715, an offset microlens arrangement is implemented in the display system 700, where the red pixel 704 is in alignment with the optical axis of the offset microlens 502. An array of RGB pixels 602 has the red pixel 704 profile that matches with the default exit pupil 414, and thus the red light 606 is not clipped. Green light 402 and blue light 604 are progressively shifted more towards the input coupler direction 706. The green light 402 is offset and the blue light 604 is even more offset than the green light 402 and is projected at an angle and partially fills the exit pupil. Furthermore, the red light 606 projected to exit pupil 414 may be shifted through proper design of the panel in the microlens array having a projector lens system such that there is no change in its overlap with the IC. In this case, there would be no efficiency drop for the red color channel.

In other embodiments (not shown), variations of the display system 700 illustrated in FIG. 7 may be implemented to achieve similar effects. An offset lens may include a centered lens and a linear wedge. For example, the linear wedge may include the microlens centered on the RGB pixels with the projector lens offset and/or shifted to orient the red light, the green light, and the blue light, emitted from the light engine onto the waveguide IC, to have a different spatial distribution profile, with the blue light more concentrated in the region closest to EPE, while the red light is more uniformly spread out. In another example, the exit pupil or lens barrel may be offset and/or shifted to orient the red light, the green light, and the blue light, emitted from the light engine onto the waveguide IC, to have different spatial distribution, with the blue light more concentrated in the region closest to EPE, while the red light is more uniformly spread out.

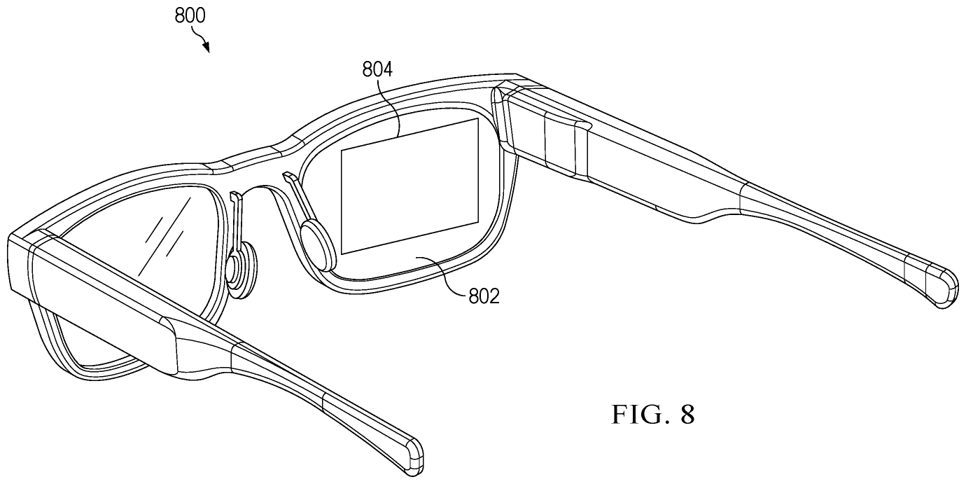

FIG. 8 illustrates a set of AR glasses implementing a waveguide optical combiner formed via one or more of the processes described above. As shown, the AR glasses 800 include a set of lenses, including a lens 802 incorporating a waveguide 804. The AR glasses 800 are configured to implement an offset microlens array on a RGB microLED panel for a diffractive waveguide based AR display, such as one of the display system 700 shown and described with reference to FIG. 7.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
providing a display panel of a light engine having red-green-blue (RGB) pixels disposed at a surface of a frontplane;
overlaying an array of microlenses over the RGB pixels;
redirecting at least a portion of collimated projected light of the RGB pixels by the microlenses of the array to an exit pupil of the light engine; and
positioning the RGB pixels so that a blue light emitted from a blue pixel of the RGB pixels has a different profile at the exit pupil compared with a red light emitted from a red pixel of the RGB pixels.

2. The method of claim 1, further comprising:
orienting the exit pupil substantially filled with red light of the collimated projected light further away from an exit pupil expander of a waveguide compared to blue light and green light of the collimated projected light.

3. The method of claim 1, further comprising:
overlaying a projector lens at a facing surface of the array of the microlenses to collimate projected light from the microlenses into the exit pupil of the light engine, and
wherein red light substantially fills the exit pupil of the light engine.

4. The method of claim 1, further comprising:
overlaying a projector lens at a facing surface of the array of the microlenses to collimate projected light from the microlenses into the exit pupil of the light engine.

5. The method of claim 1, wherein the exit pupil of the light engine is substantially coplanar with an input coupler (IC) of a waveguide, and
wherein the collimated projected light is redirected to an entrance pupil of the IC of the waveguide.

6. The method of claim 1, further comprising at least one of:
disposing a partially optically reflective coating between the RGB pixels and the microlenses; or
disposing a buffer layer between the RGB pixels and the microlenses.

7. An augmented reality (AR) display fabricated using the method of claim 1.

8. An augmented reality (AR) display comprising:
a light engine, comprising:
a three-color microscopic light-emitting diode (microLED) panel; and
an array of microlenses disposed at the three-color microLED panel and configured to redirect collimated projected light from the three-color microLED panel to an exit pupil of the light engine;
wherein a microlens of the array of the microlenses to partially cover a pixel of the three-color microLED panel so that a red pixel of the three-color microLED panel is substantially aligned with an optical axis of each microlens and a blue pixel and a green pixel are substantially offset from the microlens; and
a waveguide comprising:
an input coupler (IC), the IC has an entrance pupil, and
wherein the entrance pupil of the IC is substantially coplanar with the light engine.

9. The AR display of claim 8, wherein the three-color microLED panel has red-blue-green (RGB) pixels.

10. The AR display of claim 8, further comprising:
a projector lens is disposed at a surface of the array of microlenses to collimate projected light from the microlens into the exit pupil of the light engine, and
wherein a red light substantially fills the exit pupil of the light engine.

11. The AR display of claim 8, wherein the exit pupil of the light engine is coplanar with the IC of the waveguide, and
wherein the collimated projected light is redirected to the entrance pupil of the IC of the waveguide.

12. The AR display of claim 8, further comprising at least one of:
a partially optically reflective coating is disposed between the three-color microLED panel and a microlens; or
a buffer layer disposed between the three-color microLED panel and the microlens.
